(19) United States
(12) Patent Application Publication
(10) Pub. No.: US 2011/0133598 A1
(43) Pub. Date: Jun. 9, 2011

(54) ELECTROMECHANICAL TRANSDUCER COMPRISING A POLYURETHANE POLYMER WITH POLYTETRAMETHYLENE GLYCOL ETHER UNITS

(75) Inventors: Werner Jenninger, Koln (DE); Sebastian Dörr, Dusseldorf (DE); Joachim Wagner, Koln (DE); Evelyn Peiffer, Leverkusen (DE); Stephanie Vogel, Langenfeld (DE); Hartmut Nefzger, Pulheim (DE); Manfred Schmidt, Dormagen (DE)

(73) Assignee: Bayer MaterialScience AG, Leverkusen (DE)

(21) Appl. No.: 12/959,935

(22) Filed: Dec. 3, 2010

(30) Foreign Application Priority Data
Dec. 4, 2009 (EP) 09015051.7

(51) Int. Cl. H01L 41/193; H01L 41/22

(52) U.S. Cl. 310/311; 29/25.35

(57) ABSTRACT

The present invention provides an electromechanical transducer comprising a dielectric elastomer with contact by a first electrode and a second electrode, said dielectric elastomer comprising a polyurethane polymer comprising the reaction product of A) a polyisocyanate and/or B) a polyisocyanate prepolymer with C) a compound having at least two isocyanate-reactive groups wherein the polyisocyanate prepolymer B) and/or the compound C) having at least two isocyanate-reactive groups comprise polytetramethylene glycol ether units of the formula (I):

—[O—CH2-CH2-CH2-CH2-]n (I)

where n≧25; and with a minimum value nₘᵢₙ for the value n and a maximum value nₘₐₓ for the value n in the formula (I) selected such that the difference between nₘₐₓ and nₘᵢₙ is ≧0 to ≦4. The present invention further provides a process for producing such an electromechanical transducer, and to an electric and/or electronic device including the inventive electromechanical transducer.

### CROSS-REFERENCE TO RELATED APPLICATIONS

This application claims benefit to European Patent Application No. 09015051.7, filed Dec. 4, 2009, which is incorporated herein by reference in its entirety for all useful purposes.

### FIELD OF THE INVENTION

The present invention relates to an electromechanical transducer made from a dielectric elastomer with contacts by a first electrode and a second electrode, wherein said dielectric elastomer contains a polyurethane polymer including at least one polytetramethylene glycol ether unit. The invention further relates to a process for producing such an electromechanical transducer to an electric and/or electronic device including an inventive electromechanical transducer.

### BACKGROUND OF THE INVENTION

Electromechanical transducers play an important role in the conversion of electrical energy to mechanical energy and vice versa. Electromechanical transducers can therefore be used as sensors, actuators and/or generators.

One class of such transducers is that based on electroactive polymers. It is a constant aim to increase the properties of the electroactive polymers, especially the electrical resistance and the breakdown strength. At the same time, however, the mechanical properties of the polymers should make them suitable for uses in electromechanical transducers.

One means of increasing the dielectric constant is the addition of particular fillers. For instance, WO 2008/095621 describes carbon black-filled polyurethane materials which consist at least of polyetherurethanes, into which are incorporated polyol components formed to an extent of 50-100% by weight from polyalkylene oxides, especially polypropylene oxides, prepared by DMC catalysis, and 0-50% by weight from polyols free of catalyst residues, especially those which have been purified by distillation or by recrystallization, or those which have not been prepared by ring-opening polymerization of oxygen heterocycles. In addition, the polyurethane materials contain 0.1-30% by weight of carbon black.

Energy converters formed from film-forming aqueous polyurethane dispersions are disclosed in WO 2009/074192. Here too, the high dielectric constants and the good mechanical properties of the resulting polyurethane films are emphasized.

However, there is still a need in the art for electromechanical transducers comprising dielectric elastomers which simultaneously have high electrical resistances and high breakdown field strengths, to achieve even higher efficiencies of the transducers.

### SUMMARY OF THE INVENTION

Accordingly, the present invention provides such electromechanical transducers comprising dielectric elastomers which simultaneously have high electrical resistances and high breakdown field strengths, to achieve even higher efficiencies of the transducers.

These and other advantages and benefits of the present invention will be apparent from the Detailed Description of the Invention herein below.

### DETAILED DESCRIPTION OF THE INVENTION

The present invention will now be described for purposes of illustration and not limitation. Except in the operating examples, or where otherwise indicated, all numbers expressing quantities, percentages, OH numbers, functionalities and so forth in the specification are to be understood as being modified in all instances by the term “about.” Equivalent weights and molecular weights given herein in Daltons (Da) are number average equivalent weights and number average molecular weights respectively, unless indicated otherwise.

The present invention therefore provides an electromechanical transducer comprising a dielectric elastomer with contacts by a first electrode and a second electrode, wherein said dielectric elastomer comprises a polyurethane polymer comprising the reaction product of A) a polyisocyanate and/or B) a polyisocyanate prepolymer with C) a compound having at least two isocyanate-reactive groups wherein the polyisocyanate prepolymer B) and/or the compound C) having at least two isocyanate-reactive groups contain polytetramethylene glycol ether units of the formula (I):

—[O—CH₂—CH₂—CH₂—CH₂—]ₙ (I)

where n≧25, and with a minimum value nₘᵢₙ for the value n and a maximum value nₘₐₓ for the value n in the formula (I) selected such that the difference between nₘₐₓ and nₘᵢₙ is ≧0 to ≦4, wherein the n, nₘₐₓ and nₘᵢₙ values may be the same or different and wherein, the polyisocyanate prepolymer B) and in the compound C) having at least two isocyanate-reactive groups contain no additional polytetramethylene glycol ether units other than those of the formula (I).

The present inventors have found that the polyurethane polymers provided in the inventive electromechanical transducer have particularly high electrical resistances in combination with high breakdown field strengths. At the same time, the polyurethanes are in the form of soft elastomers. The combination of these properties may prove advantageous in electromechanical transducers.

When a mechanical stress is exerted on such a transducer, the transducer becomes deformed, for example, along its thickness and its area, and a strong electrical signal can be detected at the electrodes. Mechanical energy is thus converted to electrical energy. The inventive transducer can consequently be used either as a generator or as a sensor.

Utilizing the opposite effect, namely the conversion of electrical energy to mechanical energy, the inventive transducer, on the other hand, can equally serve as an actuator.

Suitable electrodes are in principle all materials which have a sufficiently high electrical conductivity and can advantageously follow the expansion of the dielectric elastomer. For example, the electrodes may be formed from an electrically conductive polymer, from conductive ink or from carbon black. Dielectric elastomers in the context of the present invention are elastomers which can change their shape through the application of an electric field. In the case of elastomer films, for example, the thickness can be reduced, while there is simultaneously an extension of film length in areal direction.

The thickness of the dielectric elastomer layer is preferably ≧1 μm to ≦500 μm and more preferably ≧10 μm to ≦100 μm. They may have a one-piece or multi-piece structure. For example, a multi-piece layer can be obtained by laminating individual layers onto one another.

The dielectric elastomer may, as well as the polyurethane polymer provided in accordance with the invention, have further components. Such components include, for example, crosslinkers, thickeners, cosolvents, thixotropic agents, stabilizers, antioxidants, light stabilizers, emulsifiers, surfactants, adhesives, plasticizers, hydrophobing agents, pigments, fillers and levelling aids.

Fillers in the elastomer may, for example, regulate the dielectric constant of the polymer. Examples thereof are ceramic fillers, especially barium titanate, titanium dioxide, and piezoelectric ceramics such as quartz or lead-zirconium titanate, and also organic fillers, especially those with a high electric polarizability, for example phthalocyanines.

In addition, a high dielectric constant is also achievable by the introduction of electrically conductive fillers below the percolation threshold thereof. Examples thereof are carbon black, graphite, single-wall or multi-wall carbon nanotubes, electrically conductive polymers such as polythiophenes, polyanilines or polypyrroles, or mixtures thereof. In this context, carbon black types of interest are especially those which have surface passivation, and therefore increase the dielectric constant at low concentrations below the percolation threshold, but do not lead to an increase in the conductivity of the polymer.

It is envisaged that the polyurethane polymer obtained from the reaction of a polyisocyanate A) and/or a polyisocyanate prepolymer B) with a compound C) which comprises at least two isocyanate-reactive groups. In this context, B) and/or C) have the polytetramethylene glycol ether units of the formula (I) mentioned at the outset. This gives rise to the following possibilities: A)+C) with units (I) in C); B)+C) with units (I) in B); B)+C) with units (I) in C); B)+C) with units (I) in B) and C); A)+B)+C) with units (I) in B); A)+B)+C) with units (I) in C) and finally A)+B)+C) with units (I) in B) and C).

The units (I) in the polyurethane polymer can be obtained, for example, from the reaction of polyisocyanates and/or polyisocyanate prepolymers with polyether polyols based on polymeric tetrahydrofuran (polymeric THF). These polymers can likewise also be used to form the prepolymers.

The value n in the general formula (I) indicates the chain length of the polymeric THF and thus correlates with the molecular mass of the polyol used. The value n here is at least 25. This corresponds to a polymeric THF with a molecular mass of about 1800 g/mol. It has been found that, in the case of significantly lower mean molecular masses of the polymeric THF, the desired combination of electrical resistance and breakdown field strength in the polyurethane polymer is not achieved. The value n may, for example, also be ≧27, which would correspond to a molecular mass of about 2000 g/mol. Further preferred values for n are ≧41 or ≧55.

In the polymer used in accordance with the invention, the aim is that the chain lengths of the units (I) are very substantially homogeneous. This has been achieved when the length difference between the shortest chain in the polymer and the longest chain in the polyurethane polymer is ≧0 to ≦4 —[O—CH₂—CH₂—CH₂—CH₂—] groups. This difference between nₘₐₓ and nₘᵢₙ may also be ≧0 to ≦3 or ≧1 to ≦2. In the case of very substantially homogeneous chain lengths, a very regular polyurethane polymer can be obtained. For this purpose, an exception is made in one case of the present invention. This exception relates to the case that a polyurethane polymer with components A)+B)+C) is prepared.

In that case, it is possible not only that the units (I) in the polymer which originate from the prepolymer B) and the compound C) have the same values for n, nₘₐₓ and nₘᵢₙ. Figuratively speaking, in this case, the same polymeric THF with the homogeneity of the chain lengths in B) and C) envisaged in accordance with the invention were used. However, the present inventors also contemplate that different polymeric THF polyols can be used in B) and in C) when each of them has the required homogeneity of the chain lengths. In that case, the units (I) in B) can have values for n, nₘₐₓ and nₘₘ, and the difference between nₘₐₓ and nₘᵢₙ is ≧0 to ≦4, ≧0 to ≦3 or ≧1 to ≦2. Units (I) in C) have different values for n, nₘₐₓ and nₘᵢₙ, and the difference between nₘₐₓ and nₘᵢₙ here too is ≧0 to ≦4, ≧0 to ≦3 or ≧1 to ≦2.

In addition, it is contemplated in accordance with the invention that, in the polyisocyanate prepolymer B) and in the compound with at least two isocyanate-reactive groups C), each considered alone, no further polytetramethylene glycol ether units are present apart from those of the formula (I). This means that, in the prepolymer B), no polytetramethylene glycol ether units with other values of n or the difference between nₘₐₓ and nₘᵢₙ are present, and that, in the compound C) likewise no polytetramethylene glycol ether units with other values of n or of the difference between nₘₐₓ and nₘᵢₙ are present. This too contributes to a regular structure of the polyurethane polymer.

For example, it is specifically not preferred that the polyurethane is prepared using a mixture of two different polymeric THF polyethers for the prepolymer B) or the component C). A 1:1 mixture of polymeric THFs with mean molecular masses of 1000 g/mol and 3000 g/mol respectively could also give rise to an average molecular mass of 2000 g/mol. However, the difference between the longest polymer chain (from the polymeric THF with 3000 g/mol) and the shortest polymer chain (from the polymeric THF with 1000 g/mol) would certainly be greater than four —[O—CH₂—CH₂—CH₂—CH₂—] groups.

According to the invention, suitable polyisocyanates and components A) include, for example, butylene 1,4-diisocyanate, hexamethylene 1,6-diisocyanate (HDI), isophorone diisocyanate (IPDI), trimethylhexamethylene 2,2,4- and/or 2,4,4-diisocyanate, the isomeric bis(4,4′-isocyanatocyclohexyl)methanes or mixtures thereof with any isomer content, cyclohexylene 1,4-diisocyanate, 4-isocyanatomethyloctane 1,8-diisocyanate (nonane triisocyanate), phenylene 1,4-diisocyanate, toluoylene 2,4- and/or 2,6-diisocyanate, naphthylene 1,5-diisocyanate, diphenylmethane 2,2′- and/or 2,4′- and/or 4,4′-diisocyanate, 1,3- and/or 1,4-bis(2-isocyanatoprop-2-yl)benzene (TMXDI), 1,3-bis(isocyanatomethyl)benzene (XDI), alkyl 2,6-diisocyanatohexanoates (lysine diisocyanates) with alkyl groups having 1 to 8 carbon atoms, and mixtures thereof. In addition, compounds which contain uretdione, isocyanurate, biuret, iminooxadiazinedione or oxadiazinetrione structure and are based on the diisocyanates mentioned are suitable units for component A.

The polyisocyanate prepolymers usable as component B) can be obtained by reacting one or more diisocyanates with one or more hydroxy-functional, especially polymeric, polyols, optionally with addition of catalysts and assistants and additives. Furthermore, it is additionally possible to use components for chain extension, for example with primary and/or secondary amino groups (NH₂- and/or NH-functional components), for the formation of the polyisocyanate prepolymer.

Hydroxy-functional polymeric polyols for the conversion to the polyisocyanate prepolymer B) may, in accordance with the invention, for example, be polyester polyols, polyacrylate polyols, polyurethane polyols, polycarbonate polyols, polyether polyols, polyester polyacrylate polyols, polyurethane polyacrylate polyols, polyurethane polyester polyols, polyurethane polyether polyols, polyurethane polycarbonate polyols and/or polyester polycarbonate polyols. These can be used individually or in any mixtures with one another to prepare the polyisocyanate prepolymer.

To prepare the polyisocyanate prepolymers B), diisocyanates can be reacted with the polyols at a ratio of the isocyanate groups to hydroxyl groups (NCO/OH ratio) of 2:1 to 20:1, for example of 8:1. This can form urethane and/or allophanate structures. Any proportion of unconverted polyisocyanates can subsequently be removed. For this purpose, for example, a thin-film distillation can be used, in which case products low in residual monomers, having residual monomer contents of, preferably, ≦1 percent by weight, more preferably ≦0.5 percent by weight, most preferably ≦0.1 percent by weight, are obtained. The reaction temperature may be preferably from 20° C. to 120° C., more preferably from 60° C. to 100° C. It is optionally possible, during the preparation, to add stabilizers such as benzoyl chloride, isophthaloyl chloride, dibutyl phosphate, 3-chloropropionic acid or methyl tosylate.

Moreover, it is possible to use NH₂- and/or NH-functional components in addition for chain extension in the preparation of the polyisocyanate preopolymers B).

Components suitable in accordance with the invention for chain extension are organic di- or polyamines. For example, it is possible to use ethylenediamine, 1,2-diaminopropane, 1,3-diaminopropane, 1,4-diaminobutane, 1,6-diaminohexane, isophoronediamine, isomer mixture of 2,2,4- and 2,4,4-trimethylhexamethylenediamine, 2-methylpentamethylenediamine, diethylenetriamine, diaminodicyclohexylmethane or dimethylethylenediamine, or mixtures thereof.

In addition, it is also possible to use compounds which also have secondary amino groups as well as a primary amino group, or also have OH groups as well as an amino group (primary or secondary) to prepare the polyisocyanate prepolymers B). Examples for this purpose are primary/secondary amines, such as diethanolamine, 3-amino-1-methylaminopropane, 3-amino-1-ethylaminopropane, 3-amino-1-cyclohexylaminopropane, 3-amino-1-methylaminobutane, alkanolamines such as N-aminoethylethanolamine, ethanolamine, 3-aminopropanol, neopentanolamine. For chain termination, it is customary to use amines with a group reactive toward isocyanates, such as methylamine, ethylamine, propylamine, butylamine, octylamine, laurylamine, stearylamine, isononyloxypropylamine, dimethylamine, diethylamine, dipropylamine, dibutylamine, N-methylaminopropylamine, diethyl(methyl)aminopropylamine, morpholine, piperidine, or suitable substituted derivatives thereof, amide amines formed from di-primary amines and monocarboxylic acids, monoketime of di-primary ammen, primary/tertiary amines, such as N,N-dimethylaminopropylamine.

The polyisocyanate prepolymers used in accordance with the invention as component B), or mixtures thereof, may preferably have a mean NCO functionality of ≧1.8 to ≦5, more preferably ≧2 to ≦3.5 and most preferably ≧2 to ≦2.5.

In the context of the present invention, component C) may in principle be a compound having at least two isocyanate-reactive hydroxyl groups. For example, component C) may be a polyol having at least two isocyanate-reactive hydroxyl groups.

Of course, the aforementioned conditions with regard to the presence and the form of polytetramethylene glycol ether units of the formula (I) in the polyurethane polymer apply.

The equivalents ratio used of the isocyanate groups from A) relative to the isocyanate groups from B) is advantageously between ≧1:10 and ≦10:1, more preferably ≧1:5 to ≦5:1 and most preferably ≧1:3 to ≦3:1.

In the context of the present invention, the word “a” in connection with components A), B) and C) is not used in the sense of “one”, but rather as the indeterminate article.

In one embodiment of the inventive electromechanical transducer, n in the general formula (I) is additionally ≦29. A value for n of ≧25 to ≦29 can be achieved by using a polytetramethylene glycol ether polyol with an average molecular mass of 2000 g/mol in the preparation of the polyurethane polymer. Such polyols are commercially available, for example, under the POLYTHF 2000 or TERATHANE 2000 trade names. The value of n may also be ≦28 or ≦27.

In another embodiment of the inventive electromechanical transducer, the polyurethane polymer is obtainable from the reaction of a trifunctional polyisocyanurate A) with a polytetramethylene glycol ether polyol C). The trifunctional polyisocyanurate is preferably a trimer of an aliphatic diisocyanate. It is more preferably an isocyanurate formed from three molecules of hexamethylene diisocyanate.

In a further embodiment of the inventive electromechanical transducer, the polyurethane polymer is obtainable from the reaction of a polyurethane prepolymer B) with a polyalkylene oxide polyether polyol C), and the polyurethane prepolymer B) is obtained from the reaction of a difunctional polyisocyanate with a polytetramethylene glycol ether polyol. Particularly suitable polyisocyanates for forming the prepolymer are hexamethylene diisocyanate and diphenylmethane 4,4′-diisocyanate. The prepolymer is subsequently chain-extended with a polyalkylene oxide polyether polyol. Suitable polyols for this purpose are especially polypropylene oxide polyether polyols or polypropylene oxide-polyethylene oxide ether polyols. The polyols for chain extension are preferably difunctional or trifunctional. The number-average molecular mass may, for example, be ≧2000 g/mol to ≦6000 g/mol.

In yet a further embodiment of the inventive electromechanical transducer, the polyurethane polymer is obtainable from the reaction of an isocyanate-functional polyurethane prepolymer B) with a polytetramethylene glycol ether polyol C). In this case, the polymeric THF serves to extend the prepolymer chain.

In this embodiment, it is preferred when a trifunctional polyisocyanurate A) is additionally present in the reaction to give the polyurethane polymer. The trifunctional polyisocyanurate is preferably a trimer of an aliphatic diisocyanate. It is more preferably an isocyanurate formed from three molecules of hexamethylene diisocyanate.

In yet another embodiment of the inventive electromechanical transducer, the polyurethane polymer is obtained from the reaction of a polyurethane prepolymer B) with a polytetramethylene glycol ether polyol C), and the polyurethane prepolymer B) is obtained from the reaction of a difunctional polyisocyanate with a polytetramethylene glycol ether polyol. In this case, the polymeric THF serves both to form the prepolymer and for the chain extension thereof.

In a further embodiment of the inventive electromechanical transducer, the proportion of polytetramethylene glycol ether units in the polyurethane polymer is ≧20% by weight to ≦90% by weight. This proportion is preferably between ≧25% by weight and ≦80% by weight, and more preferably between ≧30% by weight and ≦50% by weight.

In another embodiment of the inventive electromechanical transducer, the polyurethane polymer has a modulus of elasticity at an elongation of 50% of ≧0.1 MPa to ≦10 MPa. The modulus is determined here to DIN EN 150 672 1-1 and may also be ≧0.2 MPa to ≦5 MPa. In addition, the polyurethane polymer may have a maximum stress of ≧0.2 MPa, especially of ≧0.4 MPa to ≦50 MPa, and a maximum strain of ≧250%, especially of ≧350%. Furthermore, the inventive polymer element, within the working strain range of ≧50% to ≦200%, may have a stress of ≧0.1 MN to ≦1 MPa, for example of ≧0.15 MPa to ≦0.8 MPa, especially of ≧0.2 MPa to ≦0.3 MPa (determination to DIN 53504).

The present invention further provides a process for producing an electromechanical transducer, involving:
1) providing a first electrode and a second electrode;
2) providing a dielectric elastomer, said dielectric elastomer comprising a polyurethane polymer, and said polyurethane polymer comprising the reaction product of
   A) a polyisocyanate and/or B) a polyisocyanate prepolymer
   with C) a compound having at least two isocyanate-reactive groups;
   wherein the polyisocyanate prepolymer B) and/or the compound C) having at least two isocyanate-reactive groups contain polytetramethylene glycol ether units of the formula (I):

—[O—CH₂—CH₂—CH₂—CH₂—]ₙ (I)
where n≧25; and
   with a minimum value nₘᵢₙ for the value n and a maximum value nₘₐₓ for the value n in the formula (I) selected such that the difference between nₘₐₓ and nₘᵢₙ is ≧0 to ≦4;
   wherein the n, nₘₐₓ and nₘᵢₙ values may be the same or different; and
   wherein, the polyisocyanate prepolymer B) and the compound C) having at least two isocyanate-reactive groups contain no additional polytetramethylene glycol ether units other than those of the formula (I);
3) arranging the dielectric elastomer between the first electrode and the second electrode.

Details of the polyurethane polymer including the embodiments have already been described hereinabove in connection with the inventive device. To avoid unnecessary repetition, reference is made thereto with regard to the process.

In one embodiment of the process according to the invention, the dielectric elastomer is provided by applying a reaction mixture which produces the polyurethane polymer to the first and/or second electrode. The advantage of this procedure is in particular that the hardening elastomer can build up good adhesion to the electrodes.

The reaction mixture can be applied, for example, by knife-coating, painting, pouring, spinning, spraying or extrusion.

The reaction mixture is preferably dried and/or heat treated. The drying can be effected within a temperature range from 0° C. to 200° C., for example for 0.1 min to 48 h, especially for 6 h to 18 h. The heat treatment can be effected, for example, within a temperature range from 80° C. to 250° C., for example for 0.1 min to 24 h.

The present invention further relates to the use of a dielectric elastomer as an actuator, sensor and/or generator in an electromechanical transducer, wherein the dielectric elastomer comprises a polyurethane polymer and the polyurethane polymer is obtained from the reaction of

A) a polyisocyanate and/or B) a polyisocyanate prepolymer with C) a compound having at least two isocyanate-reactive groups, wherein the polyisocyanate prepolymer B) and/or the compound C) having at least two isocyanate-reactive groups comprise polytetramethylene glycol ether units of the formula (I):

—[O—CH₂—CH₂—CH₂—CH₂—]ₙ (I)

where n≧25, and with a minimum value nₘᵢₙ for the value n and a maximum value nₘₐₓ for the value n in the general formula (I) selected such that the difference between nₘₐₓ and nₘᵢₙ is ≧0 to ≦4, wherein the n, nₘₐₓ and nₘᵢₙ values may be the same or different, and wherein the polyisocyanate prepolymer B) and the compound C) having at least two isocyanate-reactive groups contain no additional polytetramethylene glycol ether units are present apart from those of the formula (I).

Details of the polyurethane polymer including the embodiments have already been described hereinabove in connection with the inventive device. To avoid unnecessary repetition, reference is made thereto with regard to the use thereof.

The inventive materials may find use in a multitude of very different applications in the electromechanical and electroacoustic sector, especially in the sector of power generation from mechanical vibrations (energy harvesting), of acoustics, of ultrasound, of medical diagnostics, of acoustic microscopy, of mechanical sensor systems, especially pressure, force and/or strain sensor systems, of robotic systems and/or of communications technology. Examples thereof are pressure sensors, electroacoustic transducers, microphones, loudspeakers, vibration transducers, light deflectors, membranes, modulators for glass fiber optics, pyroelectric detectors, capacitors and control systems and “intelligent” floors, and systems for converting water wave power, especially sea wave power, to electrical energy.

The invention further provides an electric and/or electronic device comprising an inventive electromechanical transducer.

The invention is to be illustrated further by the examples adduced below, without being restricted thereto.

### EXAMPLES

Unless characterized differently, all percentages are based on weight and all analytical measurements are based on temperatures of 23° C. NCO contents were, unless explicitly mentioned otherwise, determined volumetrically according to DIN-EN ISO 11909.

The viscosities reported were determined by means of rotational viscometry according to DIN 53019 at 23° C. with a rotational viscometer from Anton Paar Germany GmbH.

The tensile tests were conducted by means of a tensile tester from Zwick, model number 1455, equipped with a load cell of overall measurement range 1 kN according to DIN 53 504 with a pulling speed of 50 mm/min. The specimens used were S2 tensile specimens. Each measurement was conducted on three specimens prepared in the same way, and the mean of the data obtained was used for assessment. The stress in [MPa] was determined at 50% elongation.

The electrical resistance was determined by means of a laboratory setup from Keithley Instruments, model No.: 6517 A and 8009, according to ASTM D 257 (a method for determining the insulation resistance of materials).

The determination of the breakdown field strength according to ASTM D 149-97a was performed with a high-voltage HypotMAX source from Associated Research Inc. and a sample holder constructed by the inventors. The sample holder contacted the homogeneously thick polymer samples with only low mechanical preload, and prevented the user from coming into contact with the voltage. In this setup, the non-prestressed polymer film was subjected to static load with rising voltage, until there was an electrical breakdown through the film. The measurement result was the voltage attained at the breakdown, based on the thickness of the polymer film in [V/μm]. Five measurements were conducted per film, and the mean was reported.

Substances and abbreviations used:
DESMODUR N 3300: trifunctional isocyanurate based on hexamethylene diisocyanate (HDI trimer), NCO content 21.8±0.3% (according to DIN EN ISO 11 909), viscosity at 23° C. 3000±750 mPa·s, Bayer MaterialScience AG
DESMODUR 44M methylene diphenyl 4,4′-diisocyanate, Bayer MaterialScience AG
TERATHANE 2000 polytetramethylene ether glycol with Mₙ=2000 g/mol, INVISTA Resins & Fibers
TERATHANE 650 polytetramethylene ether glycol with Mₙ=650 g/mol, INVISTA Resins & Fibers
POLYTHF 2000 difunctional polytetraethylene glycol polyether with Mₙ=2000 g/mol, BASF SE
ARCOL PPG 2000 polypropylene glycol with Mₙ=2000 g/mol, Bayer MaterialScience AG
ACCLAIM 6320 trifunctional polypropylene glycol-polyethylene glycol polyether with Mₙ=6000 g/mol and a proportion of ethylene oxide units of 20% by weight, Bayer MaterialScience AG
DBTDL dibutyltin dilaurate, E. Merck KGaA

### Example 1

### Preparation of an Isocyanate-Difunctional Polyisocyanate Prepolymer

1300 g of hexamethylene 1,6-diisocyanate (HDI), 1.3 g of benzoyl chloride and 1.3 g of methyl para-toluene sulphonate were initially charged in a 4 liter four-neck flask while stirring. Within 3 hours, 1456 g of ARCOL PPG 2000 were added at 80° C. and the mixture was stirred at the same temperature for a further 1 hour. Subsequently, thin-film distillation at 130° C. and 0.1 torr distilled off the excess HDI. In the receiver flask was 1 g of chloropropionic acid. The resulting NCO prepolymer had an NCO content of 3.23% and a viscosity of 1650 mPas (25° C.).

### Example 2

### Preparation of an Isocyanate-Difunctional Polyisocyanate Prepolymer

1300 g of hexamethylene 1,6-diisocyanate (HDI) and 0.27 g of dibutyl phosphate were initially charged in a 4 liter four-neck flask while stirring. Within 3 hours, 1456 g of a difunctional polypropylene glycol polyether with a number-average molecular weight of 2000 g/mol were added at 80° C., and the mixture was stirred at the same temperature for a further 1 hour. Subsequently, thin-film distillation at 130° C. and 0.1 torr distilled off the excess HDI. The resulting NCO prepolymer had an NCO content of 3.27% and a viscosity of 1680 mPas (25° C.).

### Example 3

### Preparation of an Isocyanate-Difunctional Polyisocyanate Prepolymer

1300 g of hexamethylene 1,6-diisocyanate (HDI) and 1.3 g of benzoyl chloride were initially charged in a 4 liter four-neck flask while stirring. Within 3 hours, 1456 g of a difunctional polypropylene glycol polyether with a number-average molecular weight of 2000 g/mol were added at 80° C., and the mixture was stirred at the same temperature for a further 1 hour. Subsequently, thin-film distillation at 130° C. and 0.1 torr distilled off the excess HDI. The resulting NCO prepolymer had an NCO content of 3.27% and a viscosity of 1500 mPas (25° C.).

### Example 4

### Preparation of an Isocyanate-Tetrafunctional Polyisocyanate Prepolymer

1000 g of hexamethylene 1,6-diisocyanate (HDI) and 0.15 g of zirconium octoate were initially charged in a 4 liter four-neck flask while stirring. Then 1000 g of POLYTHF 2000 were added at 80° C. and the mixture was stirred at 115° C. for 5 hours, in the course of which 0.15 g of zirconium octoate were added three times at intervals of 1 hour. After the time had elapsed, 0.5 g of dibutyl phosphate was added. Subsequently, thin-film distillation at 130° C. and 0.1 torr distilled off the excess HDI. The resulting NCO prepolymer had an NCO content of 6.18% and a viscosity of 25 700 mPas (25° C.).

### Example 5

### Preparation of an Isocyanate-Trifunctional Polyisocyanate Prepolymer

To prepare the prepolymer, 7.15 kg of DESMODUR 44M were initially charged in a stirred vessel at a temperature of 50° C., and 45.85 kg of a trifunctional polypropylene glycol-polyethylene glycol polyether with a number-average molecular weight of 6000 g/mol and a proportion of ethylene oxide units of 0% by weight (at room temperature) were added within 15 min. Optionally, the polyether can also be initially charged at 50° C. and then the isocyanate likewise heated to 50° C. can be added. Thereafter, the mixture was heated to 100° C. for reaction and kept at this temperature for a further 7 hours. After cooling, a product was obtained with an NCO content of 2.70±0.1% and a viscosity of 4200±600 mPas (70° C.).

### Comparative Example C-1

### Preparation of a Polymer for Noninventive Use

The raw materials used were not degassed separately. 8 g of prepolymer from Example 1 were mixed with 2 g of DESMODUR N3300 in a SPEEDMIXER at 3000 rpm for a duration of 1 min, and the mixture was mixed with 16.3 g of ARCOL PPG 2000 and with 0.016 g of DBTDL in a polypropylene beaker in the SPEEDMIXER, likewise at 3000 revolutions per minute for a duration of 1 minute. The still-liquid reaction mixture was used to knife-coat films of wet film thickness 1 mm onto glass plates by hand. All films were dried after production at 80° C. in a drying cabinet overnight, and then heat treated at 120° C. for a further 5 min. After the heat treatment, the films were removable easily from the glass plate by hand.

### Comparative Example C-2

### Preparation of a Polymer for Noninventive Use

The raw materials used were not degassed separately. 8 g of prepolymer from Example 3 were mixed with 2 g of DESMODUR N3300 in a SPEEDMIXER at 3000 rpm for a duration of 1 min, and the mixture was mixed with 16.1 g of ARCOL PPG 2000 and with 0.016 g of DBTDL in a polypropylene beaker in the SPEEDMIXER, likewise at 3000 revolutions per minute for a duration of 1 minute. The still-liquid reaction mixture was used to knife-coat films of wet film thickness 1 mm onto glass plates by hand. All films were dried after production at 80° C. in a drying cabinet overnight, and then heat treated at 120° C. for a further 5 min. After the heat treatment, the films were removable easily from the glass plate by hand.

### Comparative Example C-3

### Preparation of a Polymer for Noninventive Use

The raw materials used were not degassed separately. 7.82 g of DESMODUR N3300 were mixed with 39.88 g of ARCOL PPG 2000 and with 0.12 g of DBTDL in a polypropylene beaker in a SPEEDMIXER at 3000 revolutions per minute for a duration of 1 minute. The still-liquid reaction mixture was used to knife-coat films of wet film thickness 1 mm onto glass plates by hand. All films were dried after production at 80° C. in a drying cabinet overnight, and then heat treated at 120° C. for a further 5 min. After the heat treatment, the films were removable easily from the glass plate by hand.

### Comparative Example C-4

### Preparation of a Polymer for Noninventive Use

All liquid raw materials were carefully degassed under argon in a three-stage process. 10 g of TERATHANE 650 were weighed into a 60 ml disposable mixing vessel. Subsequently, 0.005 g of dibutyltin dilaurate and 6.06 g of DESMODUR N3300 were weighed in and mixed in a SPEEDMIXER at 3000 revolutions per minute for 1 min. The reaction product was poured onto a glass plate and drawn out to a homogeneous film with a doctor blade of wet film thickness 1 mm. The film was subsequently heat treated at 80° C. for 16 h.

### Inventive Example I-1

### Preparation of a Polymer for Inventive Use

The raw materials used were not degassed separately. 8.65 g of a prepolymer from Example 4 and 25.0 g of ACCLAIM 6320 were mixed with an amount of 0.075 g of DBTDL in a polypropylene beaker in a SPEEDMIXER at 3000 revolutions per minute for a duration of 1 minute. The still-liquid reaction mixture was used to knife-coat films of wet film thickness 1 mm onto glass plates by hand. All films were dried after production at 80° C. in a drying cabinet overnight, and then heat treated at 120° C. for a further 5 min. After the heat treatment, the films were removable easily from the glass plate by hand.

### Inventive Example I-2

### Preparation of a Polymer for Inventive Use

The raw materials used were not degassed separately. 5.0 g of DESMODUR N 3300 and 20.0 g of the prepolymer from Example 2 were weighed into a polypropylene beaker and mixed with one another in a SPEEDMIXER at 3000 revolutions per minute for 1 minute. This mixture was then mixed with 38.54 g of TERATHANE 2000 with an amount of 0.01 g of DBTDL in a polypropylene beaker in a SPEEDMIXER at 3000 revolutions per minute for a duration of 1 minute. The still-liquid reaction mixture was used to knife-coat films of wet film thickness 1 mm onto glass plates by hand. All films were dried after production at 80° C. in a drying cabinet overnight, and then heat treated at 120° C. for a further 5 min. After the heat treatment, the films were removable easily from the glass plate by hand.

### Inventive Example I-3

### Preparation of a Polymer for Inventive Use

The raw materials used were not degassed separately. 19.94 g of the prepolymer from Example 4 and 30.0 g of TERATHANE 2000 were mixed with an amount of 0.03 g of DBTDL in a polypropylene beaker in a SPEEDMIXER at 3000 revolutions per minute for a duration of 1 minute. The still-liquid reaction mixture was used to knife-coat films of wet film thickness 1 mm onto glass plates by hand. All films were dried after production at 80° C. in a drying cabinet overnight, and then heat treated at 120° C. for a further 5 min. After the heat treatment, the films were removable easily from the glass plate by hand.

### Inventive Example I-4

### Preparation of a Polymer for Inventive Use

The raw materials used were not degassed separately. 14.27 g of the prepolymer from Example 4 and 30.0 g of TERATHANE 2900 were mixed with an amount of 0.03 g of DBTDL in a polypropylene beaker in a SPEEDMIXER at 3000 revolutions per minute for a duration of 1 minute. The still-liquid reaction mixture was used to knife-coat films of wet film thickness 1 mm onto glass plates by hand. All films were dried after production at 80° C. in a drying cabinet overnight, and then heat treated at 120° C. for a further 5 min. After the heat treatment, the films were removable easily from the glass plate by hand.

### Inventive Example I-5

### Preparation of a Polymer for Inventive Use

The raw materials used were not degassed separately. 1.96 g of DESMODUR N3300 were mixed with 10.0 g of TERATHANE 2000 and an amount of 0.005 g of DBTDL in a polypropylene beaker in a SPEEDMIXER at 3000 revolutions per minute for a duration of 1 minute. The still-liquid reaction mixture was used to knife-coat films of wet film thickness 1 mm onto glass plates by hand. All films were dried after production at 80° C. in a drying cabinet overnight, and then heat treated at 120° C. for a further 5 min. After the heat treatment, the films were removable easily from the glass plate by hand.

### Inventive Example I-6

### Preparation of a Polymer for Inventive Use

The raw materials used were not degassed separately. 6.7 g of DESMODUR N3300 were mixed with 50.0 g of TERATHANE 2900 and an amount of 0.05 g of DBTDL in a polypropylene beaker in a SPEEDMIXER at 3000 revolutions per minute for a duration of 1 minute. The still-liquid reaction mixture was used to knife-coat films of wet film thickness 1 mm onto glass plates by hand. All films were dried after production at 80° C. in a drying cabinet overnight, and then heat treated at 120° C. for a further 5 min. After the heat treatment, the films were removable easily from the glass plate by hand.

### Inventive Example I-7

### Preparation of a Polymer for Inventive Use

The raw materials used were not degassed separately. 55.2 g of the prepolymer from Example 5 and 33.3 g of TERATHANE 2000 were mixed with an amount of 0.00083 g of DBTDL in a polypropylene beaker in a SPEEDMIXER at 3000 revolutions per minute for a duration of 1 minute. The still-liquid reaction mixture was used to knife-coat films of wet film thickness 1 mm onto glass plates by hand. All films were dried after production at 80° C. in a drying cabinet overnight, and then heat treated at 120° C. for a further 5 min. After the heat treatment, the films were removable easily from the glass plate by hand.

The electrical resistance and the breakdown field strength of the samples were determined. The results for the noninventive examples and the examples for inventive polymer elements are shown in Table 1 below. Numerical values of the volume resistivities are reported in exponential notation. For instance, the numerical value for Example C-1 means a volume resistivity of 2.915·10¹⁰ ohm cm. In addition, the table shows the moduli of elasticity of the polymers at 50% elongation according to DIN EN 150 672 1-1.

| | Volume | Breakdown | Modulus of |
|---|---|---|---|
| | resistivity | field strength | elasticity |
| Example | [ohm cm] | [V/μm] | [MPa] |
| C-1 | 2.915E+10 | 25.9 | 0.33 |
| C-2 | 1.514E+10 | 17.5 | 0.11 |
| C-3 | 2.254E+10 | 18.0 | 0.24 |
| C-4 | 2.33E+11 | 11 | * |
| I-1 | 7.46E+10 | 32.0 | 0.60 |
| I-2 | 2.15E+11 | 45.8 | 0.95 |
| I-3 | 5.256E+12 | 57.0 | 1.84 |
| I-4 | 3.216E+12 | 55.4 | 1.66 |
| I-5 | 1.002E+11 | 26.1 | 1.89 |
| I-6 | 3.318E+12 | 64.0 | 1.77 |
| I-7 | 1.36E+12 | 101.0 | 1.05 |

* The sample tears at only 44% elongation.

It was found in the tests that the inventive polymer elements as films give significant advantages over the state of the art. Particular emphasis should be given to Comparative Example C-4, in which a higher volume resistivity than in Examples C-1, C-2 and C-3 with a short chain length of the polymeric THF, but only a comparatively low breakdown field strength was achieved.

What is particularly advantageous about use of the inventive films is the combination of very high electrical resistance and high breakthrough field strength. These inventive polymer elements can advantageously achieve particularly favorable efficiencies of the electromechanical transducers produced therewith.

Although the invention has been described in detail in the foregoing for the purpose of illustration, it is to be understood that such detail is solely for that purpose and that variations can be made therein by those skilled in the art without departing from the spirit and scope of the invention except as it may be limited by the claims.

1-13. (canceled)

14. An electromechanical transducer comprising a dielectric elastomer, a first electrode, and a second electrode; said dielectric elastomer comprising a polyurethane polymer, which comprises the reaction product of: A) a polyisocyanate and/or B) a polyisocyanate prepolymer with C) a compound having at least two isocyanate-reactive groups;
wherein the polyisocyanate prepolymer B) and/or the compound C) have at least two isocyanate-reactive groups comprising polytetramethylene glycol ether units of the formula (I):
—[O—CH₂—CH₂—CH₂—CH₂—]ₙ (I)
where n is ≧25; and
wherein n has a minimum value nₘᵢₙ and a maximum value nₘₐₓ, and n is selected such that the difference between nₘₐₓ and nₘᵢₙ is from 0 to 4;
wherein the n, nₘₐₓ and nₘᵢₙ values may be the same or different; and
wherein the polyisocyanate prepolymer B) and/or the compound C) having at least two isocyanate-reactive groups contain no additional polytetramethylene glycol ether units other than those of the formula (I).

15. The electromechanical transducer according to claim 14, wherein n is less than or equal to 29.

16. The electromechanical transducer according to claim 14, wherein the polyurethane polymer comprises the reaction product of a trifunctional polyisocyanurate A) with a polytetramethylene glycol ether polyol C).

17. The electromechanical transducer according to claim 14, wherein the polyurethane polymer comprises the reaction product of a polyurethane prepolymer B) with a polyalkylene oxide polyether polyol C), and wherein the polyurethane prepolymer B) comprises the reaction product of a difunctional polyisocyanate with a polytetramethylene glycol ether polyol.

18. The electromechanical transducer according to claim 14, wherein the polyurethane polymer comprises the reaction product of an isocyanate-functional polyurethane prepolymer B) with a polytetramethylene glycol ether polyol C).

19. The electromechanical transducer according to claim 18, further comprising a trifunctional polyisocyanurate A).

20. The electromechanical transducer according to claim 14, wherein the polyurethane polymer comprises the reaction product of a polyurethane prepolymer B) with a polytetramethylene glycol ether polyol C), and wherein the polyurethane prepolymer comprises the reaction product of a difunctional polyisocyanate with a polytetramethylene glycol ether polyol.

21. The electromechanical transducer according to claim 14, wherein the proportion of polytetramethylene glycol ether units in the polyurethane polymer is from 20% to 90% by weight.

22. The electromechanical transducer according to claim 14, wherein the polyurethane polymer has a modulus of elasticity at an elongation of 50% of from 0.1 MPa to 10 MPa.

23. A process for producing an electromechanical transducer which comprises:
1) providing a first electrode and a second electrode;
2) providing a dielectric elastomer, said dielectric elastomer comprising a polyurethane polymer comprising the reaction product of A) a polyisocyanate and/or B) a polyisocyanate prepolymer with C) a compound having at least two isocyanate-reactive groups;
wherein the polyisocyanate prepolymer B) and/or the compound C) have at least two isocyanate-reactive groups comprising polytetramethylene glycol ether units of the formula (I):
—[O—CH₂—CH₂—CH₂—CH₂—]ₙ (I)
where n≧25; and
wherein n has a minimum value nₘᵢₙ and a maximum value nₘₐₓ, and n is selected such that the difference between nₘₐₓ and nₘᵢₙ is from 0 to 4;
wherein the n, nₘₐₓ and nₘᵢₙ values may be the same or different; and
wherein the polyisocyanate prepolymer B) and/or the compound C) having at least two isocyanate-reactive groups contain no additional polytetramethylene glycol ether units other than those of the formula (I);
3) arranging the dielectric elastomer between the first electrode and the second electrode.

24. The process according to claim 23, wherein the dielectric elastomer is provided by applying a reaction mixture which leads to the polyurethane polymer to the first and/or second electrode.

25. An actuator, sensor or generator comprising the electromechanical transducer according to claim 14.

26. An electric and/or an electronic device comprising the electromechanical transducer according to claim 14.
